(19) United States
(12) Patent Application Publication
(10) Pub. No.: US 2005/0227187 A1
(43) Pub. Date: Oct. 13, 2005

(54) Ionic fluid in supercritical fluid for semiconductor processing

(75) Inventor: Paul E. Schilling, Granite Bay, CA (US)

Correspondence Address: HAVERSTOCK & OWENS LLP, 162 NORTH WOLFE ROAD, SUNNYVALE, CA, 94086, US

(73) Assignee: Supercritical Systems Inc.

(21) Appl. No.: 11/034,585

(22) Filed: Jan. 12, 2005

Related U.S. Application Data
(63) Continuation-in-part of application No. 10/379,984, filed on Mar. 4, 2003.
(60) Provisional application No. 60/361,917, filed on Mar. 4, 2002.
(60) Provisional application No. 60/369,052, filed on Mar. 29, 2002.

(51) Int. Cl. G03F 7/42

(52) U.S. Cl. 430/329

(57) ABSTRACT

A method of removing post-etch residue from a patterned low-k dielectric layer is disclosed. The low-k dielectric layer preferably comprises a porous silicon oxide-based material with the post-etch residue thereon. The post-etch residue is a polymer, a polymer contaminated with an inorganic material, an anti-reflective coating and/or a combination thereof. In accordance the method of the present invention, the post-etch residue is removed by treating the patterned low-k dielectric layer to a cleaning solution comprising supercritical carbon dioxide and an amount of an ionic fluid that preferably includes a salt with cyclic a nitrogen cation structure, such as an imidazolium or pyridinium ion, and a suitable anion, including but not limited to, a chloride, a bromide, a tetrafluoroborate, a methyl sulfate and a hexafluorophosphate anion.

### CROSS-REFERENCE TO RELATED APPLICATIONS

This patent application is a continuation-in-part (CIP) of the co-pending U.S. patent application, Ser. No. 10/379,984 filed Mar. 4, 2003, and entitled “METHODS OF PASSIVATING POROUS LOW-K DIELECTRIC FILM” which claims priority under 35 U.S.C. 119 (e) of the U.S. Provisional Patent Application, Ser. No. 60/361,917 filed Mar. 4, 2002, and entitled “METHODS OF PASSIVATING POROUS LOW-K DIELECTRIC FILM” and the U.S. Provisional Patent Application, Ser. No. 60/369,052 filed Mar. 29, 2002, and entitled “USE OF SUPERCRITICAL CO₂ PROCESSING FOR INTEGRATION AND FORMATION OF ULK DIELECTRICS”. The co-pending U.S. patent application, Ser. No. 10/379,984 filed, Mar. 4, 2003, and entitled “METHODS OF PASSIVATING POROUS LOW-K DIELECTRIC FILM”; the Provisional Patent Application, Ser. No. 60/361,917 filed Mar. 4, 2002, and entitled “METHODS OF PASSIVATING POROUS LOW-K DIELECTRIC FILM”; and the Provisional Patent Application, Ser. No. 60/369,052 filed Mar. 29, 2002, and entitled “USE OF SUPERCRITICAL CO₂ PROCESSING FOR INTEGRATION AND FORMATION OF ULK DIELECTRICS” are all hereby incorporated by reference.

### FIELD OF THE INVENTION

The invention in general relates to the field of semiconductor wafer processing. More particularly, the invention relates to cleaning porous and non-porous dielectric material having various dielectric constants with supercritical processing solutions.

### BACKGROUND OF THE INVENTION

Semiconductor fabrication generally uses photoresist in etching and other processing steps. In the etching steps, a photoresist masks areas of the semiconductor substrate that are not etched. Examples of the other processing steps include using a photoresist to mask areas of a semiconductor substrate in an ion implantation step or using the photoresist as a blanket protective coating of a processed wafer or using the photoresist as a blanket protective coating of a MEMS (micro electro-mechanical system) device.

State of the art integrated circuits can contain up to 6 million transistors and more than 800 meters of wiring. There is a constant push to increase the number of transistors on wafer-based integrated circuits. As the number of transistors is increased, there is a need to reduce the cross-talk between the closely packed wires in order to maintain high performance requirements. The semiconductor industry is continuously looking for new processes and new materials that can help improve the performance of wafer-based integrated circuits.

Materials exhibiting low dielectric constants of between 3.5-2.5 are generally referred to as low-k materials and porous materials with dielectric constant of 2.5 and below are generally referred to as ultra low-k (ULK) materials. For the purpose of this application low-k materials refer to both low-k and ultra low-k materials. Low-k materials have been shown to reduce cross-talk and provide a transition into the fabrication of even smaller integrated circuit geometries. Low-k materials have also proven useful for low temperature processing. For example, spin-on-glass materials (SOG) and polymers can be coated onto a substrate and treated or cured with relatively low temperature to make porous silicon oxide-based low-k layers. Silicon oxide-based herein does not strictly refer silicon-oxide materials. In fact, there are a number of low-k materials that have silicon oxide and hydrocarbon components and/or carbon, wherein the formula is SiOxCxHz, referred to herein as hybrid materials and designated herein as MSQ materials. It is noted, however, that MSQ is often designated to mean Methyl Silsesquioxane, which is an example of the hybrid low-k materials described above. Some low-k materials such as carbon doped oxide (COD) or fluorinated silicon glass (FSG), are deposited using chemical vapor deposition techniques, while other low-k materials, such as MSQ, porous-MSQ, and porous silica, are deposited using a spin-on process.

While low-k materials are promising materials for fabrication of advanced micro circuitry, they also provide several challenges in that they tend be less robust than a more traditional dielectric layer and can be damaged by etch and plasma ashing process generally used in pattern dielectric layer in wafer processing, especially in the case of the hybrid low-k materials, such as described above. Further, silicon oxide-based low-k materials tend to be highly reactive after patterning steps. The hydrophillic surface of the silicon oxide-based low-k material can readily absorb water and/or react with other vapors and/or process contaminants that can alter the electrical properties of the dielectric layer itself and/or diminish the ability to further process the wafer.

What is needed is a method of cleaning a low-k layer especially after a patterning step where the method includes processing steps for removing contaminants (post-etch and/or post-ash residue) after a patterning step.

### SUMMARY OF THE INVENTION

The present invention is directed to a method of and system for treating a substrate structure with a supercritical cleaning solution, preferably to remove a post-etch and/or post-ash residue from the substrate structure. Post-etch and/or post-ash residues include, but are not limited to, polymer residues, such as a photoresist polymer, and/or an organic spin-on anti-reflective polymer residues. Post-etch and/or post-ash residue, in accordance with the embodiments of the invention, also can include inorganic materials, such as phosphorus, boron and arsenic embedded in a photoresist polymer and/or an organic spin-on anti-reflective polymer, for example during an ion-implantation step.

In accordance with the embodiments of the present invention, a supercritical cleaning solution is generated which comprises supercritical carbon dioxide and an amount an ionic fluid. An ionic fluid generally refers to herein as a salt, or combination of salts, that are liquid at or near room temperature (22 degrees Celsius). These salts can be partially miscible in an organic solvent and can have a profound effect on the physical, chemical, and electrical properties of the resultant solution.

In accordance with the embodiments of the invention, the ionic fluid can comprise a salt with a heterocyclic structure. Preferably, the heterocyclic structure comprises nitrogen, such an imidazolium ion or pyridinium ion that is coupled with a suitable anion, including but not limited to chloride, bromide, tetrafluoroborate, methyl sulfate, hexafluorophosphate anions, and combinations thereof.

In accordance with the embodiments of the present invention, a supercritical cleaning solution comprises supercritical carbon dioxide and an amount of a cleaning agent that is preferably an ionic fluid. The ionic fluid can be introduced into supercritical carbon dioxide directly or with an organic solvent, such as N,N-dimethylacetamide (DMAc), gamma-butyrolactone (BLO), dimethyl sulfoxide (DMSO), ethylene carbonate (EC), N-methylpyrrolidone (NMP), dimethylpiperidone, propylene carbonate, and alcohols (such a methanol, ethanol and 1-propanol) or combinations thereof, to help introduce the ionic fluid into the supercritical CO₂.

In accordance with an embodiment of the invention, a supercritical cleaning process is performed that includes generating a supercritical cleaning solution comprising ionic liquid in a processing chamber with the substrate structure. The supercritical cleaning solution is preferably circulated around or over the substrate structure, subjected to a plurality of decompression/recompression cycles and is then vented away from the substrate structure removing residues therewith. After the substrate structure is treated with a supercritical cleaning solution, the substrate structure is preferably treated with a supercritical rinsing solution, as explained in detail below.

The method of the present invention is particularly well suited for removing post-etch and/or post-ash residues from substrate structures comprising a patterned low-k dielectric layer formed from silicon oxide-based materials, wherein the silicon-oxide based material includes, but is not limited to carbon doped oxide (COD), a spin-on-glass (SOG) and fluoridated silicon glass (FSG).

During a supercritical cleaning process, the semiconductor substrate is maintained at temperatures in a range of 40 to 200 degrees Celsius, and preferably at a temperature of between approximately 50 degrees Celsius and approximately 150 degrees Celsius, and at pressures in a range of 1,070 to 9,000 psi, and preferably at a pressure between approximately 1,500 psi and approximately 3,500 psi, while a supercritical cleaning and/or rinsing solution, such as described herein, is circulated over the surface of the semiconductor substrate and the structures therein. In addition, the surface of the semiconductor substrate and the structures therein can be dried prior to the cleaning step.

Further details of supercritical systems suitable for treating wafer substrates to supercritical processing solutions are further described in U.S. patent application Ser. No. 09/389,788, filed Sep. 3, 1999, and entitled “REMOVAL OF PHOTORESIST AND PHOTORESIST RESIDUE FROM SEMICONDUCTORS USING SUPERCRITICAL CARBON DIOXIDE PROCESS” and U.S. patent application Ser. No. 09/697,222, filed Oct. 25, 2000, and entitled “REMOVAL OF PHOTORESIST AND RESIDUE FROM SUBSTRATE USING SUPERCRITICAL CARBON DIOXIDE PROCESS”, both of which are hereby incorporated by reference.

### BRIEF DESCRIPTION OF THE DRAWINGS

A more complete appreciation of various embodiments of the invention and many of the attendant advantages thereof will become readily apparent with reference to the following detailed description, particularly when considered in conjunction with the accompanying drawings, in which:

FIGS. 1A-B schematically illustrate ionic fluids with imidazolium ion and a pyridinium ion structures, respectively;

FIG. 2 shows an exemplary block diagram of a processing system in accordance with an embodiment of the invention;

FIG. 3 illustrates an exemplary graph of pressure versus time for a supercritical process in accordance with an embodiment of the invention; and

FIG. 4 shows a simplified flow diagram outlining steps for diagram outlining the steps of removing a post-etch and/or posh-ash residue form a substrate structure using a supercritical cleaning solution comprising an ionic fluid, in accordance with the embodiments of the invention.

### DETAILED DESCRIPTION OF SEVERAL EMBODIMENTS

In semiconductor fabrication, a dielectric layer is generally patterned using a photoresist mask in one or more etching and ashing steps. Generally, to obtain the high resolution line widths and high feature aspect ratios, an anti-reflective coating is required. In earlier processes, anti-reflective coating (ARC) of titanium nitride (TiN) was vapor deposited on the dielectric layer and the TiN anti-reflective coatings would not be removed after patterning but rather remain a part of the device fabricated. With new classes of low dielectric layers that can be made to be very thin, TiN anti-reflective coatings are not preferred because the electrical properties, namely dielectric constant, of the anti-reflective coatings can dominate over the electrical properties of the dielectric layer. Accordingly, polymeric spin-on anti-reflective coatings with an anti-reflective dye that can be removed after a patterning step are preferred. Regardless of the materials that are used in the patterning steps, after patterning the dielectric layer these materials are preferably removed from the dielectric layer after the patterning process is complete.

Low-k materials have been shown to reduce cross-talk and provide a transition into the fabrication of even smaller geometry integrated circuitry. Low-k materials also provide a method for low temperature processing. For example, spin-on-glass materials (SOG) and polymers can be coated onto a substrate and treated or cured with relatively low temperature to make porous siloxane-based coatings with k-values of 2.0 or below.

While low-k materials are promising materials for fabricating advanced micro circuitry, they also provide several challenges. Most notably, they are not always compatible with other wafer fabrication steps and they tend to be less robust.

A further problem can arise when the low-k dielectric layer is doped through a photoresist mask using ion implantation. Ion implantation through a mask can result in inorganic contaminants that are embedded in the polymeric mask. These inorganic contaminants can render the photoresist difficult to remove. Further, generally following an etching step, remaining photoresist tends to exhibit a hardened character even without inorganic contaminants making the photoresist difficult to remove. Accordingly, hardened residue often requires the use of aggressive chemistries to thoroughly remove them.

A number of techniques and systems have been developed which utilize supercritical solutions for cleaning wafers in a post-etch cleaning process. While these processes show considerable promise for cleaning post-etch residues from a wafer, some of the cleaning chemistries used are too aggressive to be used to remove post-etch residue for low-k dielectric layers.

The present invention provides cleaning and/or rinsing chemistries that are suitably selective when removing post-etch and/or post-ash residues from low-k layers and do not cause significant damage or degradation to a pattern on the low-k dielectric layer. Preferably, the cleaning chemistries used are suitable for removing polymer residues, such as photoresist polymer and spin-on anti-reflective polymer coatings and/or such polymers containing inorganic contaminants, such as boron, arsenic, phosphorus and/or metal contaminants.

The present invention is directed to a method and system for removing a residue from a substrate material, including but not limited to semiconductor-based, dielectric-based, and metal-based substrate materials. The present invention preferably utilizes a supercritical CO₂ cleaning solution comprising supercritical carbon dioxide and an amount of an ionic fluid suitable for removing a post-etch residue from silicon oxide-based material.

As described herein, ionic fluids generally refer to ion species or salts that are liquid at or near room temperature and are preferably liquid at temperatures above 10 degrees Celsius. Ionic fluids preferably comprise heterocyclic structures that are anionic or cationic structures with suitable counter ion In accordance with the preferred embodiment of the invention, ionic fluids comprise one or more heterocyclic nitrogen cation structures with one or more suitable anion structures that can be combined with supercritical carbon dioxide to form a supercritical cleaning solution, as described in detail herein.

Typically, during wafer processing the photoresist is placed on the wafer to mask a portion of the wafer in a preceding semiconductor fabrication process step such as an etching step. In the etching step, the photoresist masks areas of the wafer that are not etched while the non-masked regions are etched. In the etching step, the photoresist and the wafer are etched, producing etch features while also producing the photoresist residue and the etch residue. Etching of the photoresist produces the photoresist residue. Etching of the etch features produces the post-etch residue. The photoresist and etch residue generally coat sidewalls of the etch features.

In some etching steps, the photoresist is not etched to completion so that a portion of the photoresist remains on the wafer following the etching step. In these etching steps, the etching process hardens the remaining photoresist. In this etching step, the photoresist is etched to completion so that no photoresist remains on the wafer after such etching steps. In the latter case only the residue, that is the photoresist residue and the etch residue, remains on the wafer.

The present invention is preferably directed to removing photoresist for 0.25 micron and smaller geometries. In other words, the present invention is preferably directed to removing I-line exposed photoresists and smaller wavelength exposed photoresists. These are UV, deep UV, and smaller geometry photoresists. Alternatively, the present invention is directed to removing larger geometry photoresists.

While the present invention is described in relation to applications for removing post etch residues typically used in wafer processing, it will be clear to one skilled in the art that the present invention can be used to remove any number of different residues (including polymers and oil) from any number of different materials (including silicon nitrides) and structures, including micro-mechanical, micro-optical, micro-electrical structures and combination thereof.

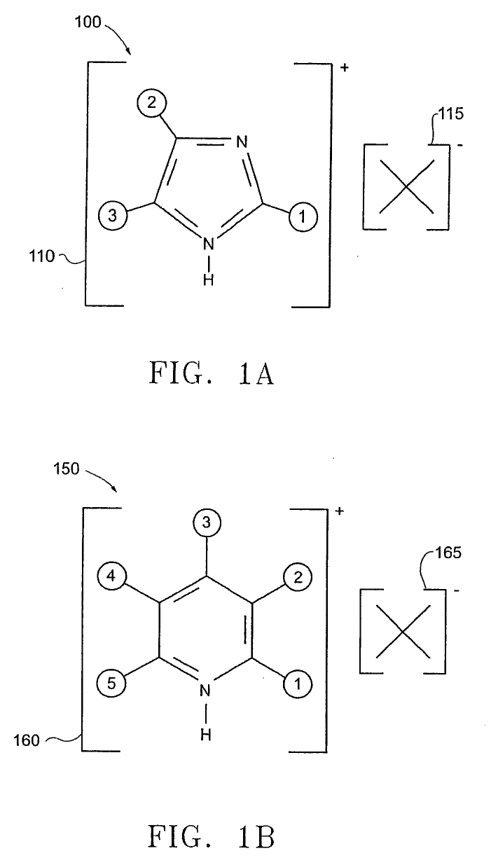

Referring now to FIG. 1A, in accordance with one embodiment of the invention, an ionic fluid 100 comprises an imidazolium ion 110 and a suitable anion 115, including but not limited to chloride, bromide, tetrafluoroborate, methyl sulfate, and hexafluorophosphate anions. The imidazolium ion 110 has hydrogen atoms, organic groups, or combinations thereof occupying positions 1, 2, and 3. Suitable organic groups for occupying the positions 1, 2, and 3 include, but are not limited to, saturated hydrocarbon, unsaturated hydrocarbon and an aromatic hydrocarbon groups.

Now referring to FIG. 1B, in accordance with further embodiments of the invention, an ionic fluid 150 comprises a pyridinium ion 160 and a suitable anion 165, including but not limited to chloride, bromide, tetrafluoroborate, methyl sulfate, and hexafluorophosphate anions. The pyridinium ion 160 has hydrogen atoms, organic groups, or combinations thereof occupying positions 1, 2, 3, 4, and 5. Suitable organic groups for occupying the positions 1, 2, 3, 4, and 5 include, but are not limited to, saturated hydrocarbon, unsaturated hydrocarbon and an aromatic hydrocarbon group.

Now referring to FIGS. 1A-B, in accordance with the method of the invention, an amount of one or more ionic fluids 100 and 150 are combined with supercritical carbon dioxide to form a supercritical cleaning solution for removing a post etch residue from a wafer substrate. Preferably the amount of ionic fluid added to a supercritical carbon dioxide to form the supercritical cleaning solution corresponds to a concentration in a range (0.1-0.5 percent by weight).

Preferably, the supercritical cleaning chemistry including a solution with one or more ionic fluids is combined with supercritical carbon dioxide along with one or more carrier solvents in a concentration in a range (0.1-3 percent by weight). The carrier solvent can also help in the dissolution or removal of residue from a substrate material in the cleaning process. Suitable carrier solvents include, but are not limited to, N,N-dimethylacetamide (DMAc), gamma-butyrolactone (BLO), dimethyl sulfoxide (DMSO), ethylene carbonate (EC), N-methylpyrrolidone (NMP), dimethylpiperidone, propylene carbonate, alcohols (such a methanol, ethanol and 2-propanol) and combinations thereof.

The present invention is particularly well suited for removing post etch photopolymer from a wafer material and even more specifically is well suited to remove a post etch photopolymer and/or a polymeric anti-reflective coating layer from a low-k silicon oxide-based layer, including low-k layers formed from porous MSQ and porous SiO₂ (e.g., Honeywell's NANOGLASS®).

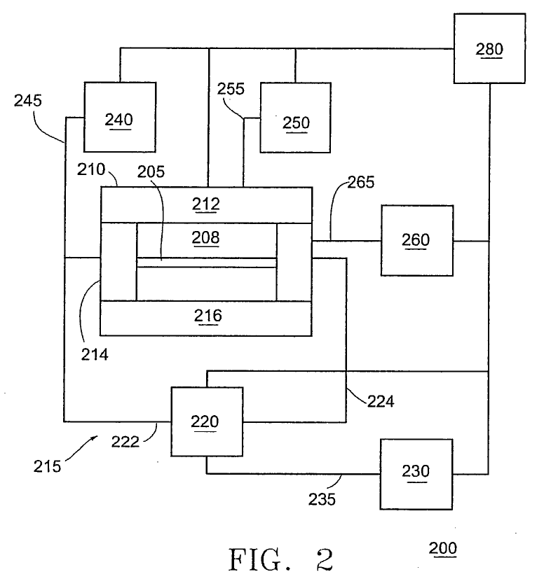

FIG. 2 shows an exemplary block diagram of a processing system in accordance with an embodiment of the invention. In the illustrated embodiment, processing system 200 comprises a process module 210, a recirculation system 220, a process chemistry supply system 230, a carbon dioxide supply system 240, a pressure control system 250, an exhaust system 260, and a controller 280. The processing system 200 can operate at pressures that can range from 1000 psi. to 20,000 psi. In addition, the processing system 200 can operate at temperatures that can range from 40 to 300 degrees Celsius.

The controller 280 can be coupled to the process module 210, the recirculation system 220, the process chemistry supply system 230, the carbon dioxide supply system 240, the pressure control system 250, and the exhaust system 260. Alternately, controller 280 can be coupled to one or more additional controllers/computers (not shown), and controller 280 can obtain setup and/or configuration information from an additional controller/computer.

In FIG. 2, singular processing elements (210, 220, 230, 240, 250, 260, and 280) are shown, but this is not required for the invention. The semiconductor processing system 200 can comprise any number of processing elements having any number of controllers associated with them in addition to independent processing elements.

The controller 280 can be used to configure any number of processing elements (210, 220, 230, 240, 250, and 260), and the controller 280 can collect, provide, process, store, and display data from processing elements. The controller 280 can comprise a number of applications for controlling one or more of the processing elements. For example, controller 280 can include a GUI component (not shown) that can provide easy to use interfaces that enable a user to monitor and/or control one or more processing elements.

The process module 210 can include an upper assembly 212, a frame 214, and a lower assembly 216. The upper assembly 212 can comprise a heater (not shown) for heating the process chamber, the substrate, or the processing fluid, or a combination of two or more thereof. Alternately, a heater is not required. The frame 214 can include means for flowing a processing fluid through the processing chamber 208. In one example, a circular flow pattern can be established, and in another example, a substantially linear flow pattern can be established. Alternately, the means for flowing can be configured differently. The lower assembly 216 can comprise one or more lifters (not shown) for moving the chuck 218 and/or the substrate 205. Alternately, a lifter is not required.

In one embodiment, the process module 210 can include a holder or chuck 218 for supporting and holding the substrate 205 while processing the substrate 205. The holder or chuck 218 can also be configured to heat or cool the substrate 205 before, during, and/or after processing the substrate 205. Alternately, the process module 210 can include a platen for supporting and holding the substrate 205 while processing the substrate 205.

A transfer system (not shown) can be used to move a substrate into and out of the processing chamber 208 through a slot (not shown). In one example, the slot can be opened and closed by moving the chuck, and in another example, the slot can be controlled using a gate valve.

The substrate can include semiconductor material, metallic material, dielectric material, ceramic material, or polymer material, or a combination of two or more thereof. The semiconductor material can include Si, Ge, Si/Ge, or GaAs. The metallic material can include Cu, Al, Ni, Pb, Ti, Ta, or W, or combinations of two or more thereof. The dielectric material can include Si, O, N, or C, or combinations of two or more thereof. The ceramic material can include Al, N, Si, C, or O, or combinations of two or more thereof.

The recirculation system can be coupled to the process module 210 using one or more inlet lines 222 and one or more outlet lines 224. The recirculation system 220 can comprise one or more valves for regulating the flow of a supercritical processing solution through the recirculation system and through the process module 210. The recirculation system 220 can comprise any number of back-flow valves, filters, pumps, and/or heaters (not shown) for maintaining a supercritical processing solution and flowing the supercritical process solution through the recirculation system 220 and through the processing chamber 208 in the process module 210.

Processing system 200 can comprise a chemistry supply system 230. In the illustrated embodiment, the chemistry supply system is coupled to the recirculation system 220 using one or more lines 235, but this is not required for the invention. In alternate embodiments, the chemical supply system can be configured differently and can be coupled to different elements in the processing system. For example, the chemistry supply system 230 can be coupled to the process module 210.

The chemistry supply system 230 can comprise a cleaning chemistry assembly (not shown) for providing cleaning chemistry for generating supercritical cleaning solutions within the processing chamber. In one embodiment, the cleaning chemistry can include an ionic fluid that can comprise an imidazolium ion and a suitable anion, including but not limited to chloride, bromide, tetrafluoroborate, methyl sulfate, and hexafluorophosphate anions. For example, the imidazole structure can be as shown in FIG. 1, and the imidazole structure 110 can include hydrogen atoms, organic groups, or combinations thereof occupying positions 1, 2, and 3. In various embodiments, suitable organic groups can occupy the positions 1, 2, and 3, and may include, but are not limited to, saturated hydrocarbon, unsaturated hydrocarbon, and aromatic hydrocarbon groups.

In accordance with further embodiments of the invention, the cleaning chemistry can include an ionic fluid that can comprise a pyridinium ion and a suitable anion, including but not limited to chloride, bromide, tetrafluoroborate, methyl sulfate, and hexafluorophosphate anions. For example, the pyridinium ion can be as shown in FIG. 1, and the pyridinium ion 160 can include hydrogen atoms, organic groups, or combinations thereof occupying positions 1, 2, 3, 4, and 5. In various embodiments, suitable organic groups can occupy positions 1, 2, 3, 4, and 5, and may include, but are not limited to, saturated hydrocarbon, unsaturated hydrocarbon, and aromatic hydrocarbon group.

In addition, the cleaning chemistry can include one or more carrier solvents, such as N,N-dimethylacetamide (DMAc), gamma-butyrolactone (BLO), dimethyl sulfoxide (DMSO), ethylene carbonate (EC), N-methylpyrrolidone (NMP), dimethylpiperidone, propylene carbonate, and alcohols (such a methanol, ethanol and 2-propanol).

The chemistry supply system 230 can comprise a rinsing chemistry assembly (not shown) for providing rinsing chemistry for generating supercritical rinsing solutions within the processing chamber. The rinsing chemistry can include one or more organic solvents including, but not limited to, alcohols and ketones. In one embodiment, the rinsing chemistry can comprise solvents, such as N,N-dimethylacetamide (DMAc), gamma-butyrolactone (BLO), dimethyl sulfoxide (DMSO), ethylene carbonate (EC), N-methylpyrrolidone (NMP), dimethylpiperidone, propylene carbonate, and alcohols (such a methanol, ethanol and 2-propanol).

The processing system 200 can comprise a carbon dioxide supply system 240. As shown in FIG. 2, the carbon dioxide supply system 240 can be coupled to the process module 210 using one or more lines 245, but this is not required. In alternate embodiments, carbon dioxide supply system 240 can be configured differently and coupled differently. For example, the carbon dioxide supply system 240 can be coupled to the recirculation system 220.

The carbon dioxide supply system 240 can comprise a carbon dioxide source (not shown) and a plurality of flow control elements (not shown) for generating a supercritical fluid. For example, the carbon dioxide source can include a CO₂ feed system, and the flow control elements can include supply lines, valves, filters, pumps, and heaters. The carbon dioxide supply system 240 can comprise an inlet valve (not shown) that is configured to open and close to allow or prevent the stream of supercritical carbon dioxide from flowing into the processing chamber 208. For example, controller 280 can be used to determine fluid parameters such as pressure, temperature, process time, and flow rate.

The processing system 200 can also comprise a pressure control system 250. As shown in FIG. 2, the pressure control system 250 can be coupled to the process module 210 using one or more lines 255, but this is not required. In alternate embodiments, pressure control system 250 can be configured differently and coupled differently. The pressure control system 250 can include one or more pressure valves (not shown) for exhausting the processing chamber 208 and/or for regulating the pressure within the processing chamber 208. Alternately, the pressure control system 250 can also include one or more pumps (not shown). For example, one pump may be used to increase the pressure within the processing chamber, and another pump may be used to evacuate the processing chamber 208. In another embodiment, the pressure control system 250 can comprise means for sealing the processing chamber. In addition, the pressure control system 250 can comprise means for raising and lowering the substrate and/or the chuck.

Furthermore, the processing system 200 can comprise an exhaust control system 260. As shown in FIG. 2, the exhaust control system 260 can be coupled to the process module 210 using one or more lines 265, but this is not required. In alternate embodiments, exhaust control system 260 can be configured differently and coupled differently. The exhaust control system 260 can include an exhaust gas collection vessel (not shown) and can be used to remove contaminants from the processing fluid. Alternately, the exhaust control system 260 can be used to recycle the processing fluid.

Controller 280 can use pre-process data, process data, and post-process data. For example, pre-process data can be associated with an incoming substrate. This pre-process data can include lot data, batch data, run data, composition data, and history data. The pre-process data can be used to establish an input state for a wafer. Process data can include process parameters. Post processing data can be associated with a processed substrate.

The controller 280 can use the pre-process data to predict, select, or calculate a set of process parameters to use to process the substrate. For example, this predicted set of process parameters can be a first estimate of a process recipe. A process model can provide the relationship between one or more process recipe parameters or set points and one or more process results. A process recipe can include a multi-step process involving a set of process modules. Post-process data can be obtained at some point after the substrate has been processed. For example, post-process data can be obtained after a time delay that can vary from minutes to days. The controller can compute a predicted state for the substrate based on the pre-process data, the process characteristics, and a process model. For example, a cleaning rate model can be used along with a contaminant level to compute a predicted cleaning time. Alternately, a rinse rate model can be used along with a contaminant level to compute a processing time for a rinse process.

It will be appreciated that the controller 280 can perform other functions in addition to those discussed here. The controller 280 can monitor the pressure, temperature, flow, or other variables associated with the processing system 200 and take actions based on these values. For example, the controller 280 can process measured data, display data and/or results on a GUI screen, determine a fault condition, determine a response to a fault condition, and alert an operator. The controller 280 can comprise a database component (not shown) for storing input and output data.

In a supercritical cleaning/rinsing process, the desired process result can be a process result that is measurable using an optical measuring device. For example, the desired process result can be an amount of contaminant in a via or on the surface of a substrate. After each cleaning process run, the desired process result can be measured.

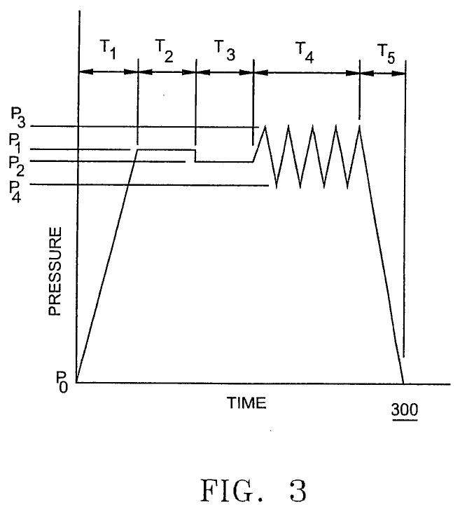

FIG. 3 illustrates an exemplary graph of pressure versus time for a supercritical process step in accordance with an embodiment of the invention. In the illustrated embodiment, a graph 300 of pressure versus time is shown, and the graph 300 can be used to represent a supercritical cleaning process step, a supercritical rinsing process step, or a supercritical curing process step, or a combination thereof. Alternately, different pressures, different timing, and different sequences may be used for different processes.

Now referring to both FIGS. 2 and 3, prior to an initial time T₀, the substrate to be processed can be placed within the processing chamber 208 and the processing chamber 208 can be sealed. For example, during cleaning and/or rinsing processes, a substrate can have post-etch and/or post-ash residue thereon. The substrate, the processing chamber, and the other elements in the recirculation loop 215 (FIG. 2) can be heated to an operational temperature. For example, the operational temperature can range from 40 to 300 degrees Celsius. For example, the processing chamber 208, the recirculation system, and piping coupling the recirculation system to the processing chamber can form a recirculation loop.

From the initial time T₀ through a first duration of time T₁, the elements in the recirculation loop 215 (FIG. 2) can be pressurized. During a first portion of the time T₁, a temperature controlled fluid can be provided into the recirculation loop 215 (FIG. 2). In one embodiment, the carbon dioxide supply system 240 can be operated during a pressurization process and can be used to fill the recirculation loop with temperature-controlled fluid. The carbon dioxide supply system 240 can comprise means for filling the recirculation loop with the temperature-controlled fluid, and the temperature variation of the temperature-controlled fluid can be controlled to be less than approximately 10 degrees Celsius during the pressurization process. Alternately, the temperature variation of the temperature-controlled fluid can be controlled to be less than approximately 5 degrees Celsius during the pressurization process. In alternate embodiments, the carbon dioxide supply system 240 and/or the pressure control system 250 can be operated during a pressurization process and can be used to fill the recirculation loop with temperature-controlled fluid.

For example, a supercritical fluid, such as substantially pure CO₂, can be used to pressurize the elements in the recirculation loop 215 (FIG. 2). During time T₁, a pump (not shown) in the recirculation system 220 FIG. 2) can be started and can be used to circulate the temperature controlled fluid through the processing chamber 208 and the other elements in the recirculation loop 215 (FIG. 2).

In one embodiment, when the pressure in the processing chamber 208 reaches an operational pressure Pₒ (approximately 2,500 psi), process chemistry can be injected into the processing chamber 208, using the process chemistry supply system 230. In an alternate embodiment, process chemistry can be injected into the processing chamber 208, using the process chemistry supply system 230 when the pressure in the processing chamber 208 exceeds a critical pressure Pc (1,070 psi). In other embodiments, process chemistry may be injected into the processing chamber 208 before the pressure exceeds the critical pressure Pc (1,070 psi) using the process chemistry supply system 230. In other embodiments, process chemistry is not injected during the T₁ period.

In one embodiment, process chemistry is injected in a linear fashion, and the injection time can be based on a recirculation time. For example, the recirculation time can be determined based on the length of the recirculation path and the flow rate. In other embodiments, process chemistry may be injected in a non-linear fashion. For example, process chemistry can be injected in one or more steps.

The process chemistry can include a cleaning agent, a rinsing agent, or a drying agent, or a combination thereof that is injected into the supercritical fluid. One or more injections of process chemistries can be performed over the duration of time T₁ to generate a supercritical processing solution with the desired concentrations of chemicals. The process chemistry, in accordance with the embodiments of the invention, can also include one more or more carrier solvents.

The process chemistry can include an ionic fluid and a solvent that is injected into the supercritical fluid. The ionic fluid can comprise an imidazolium ion and a suitable anion, including but not limited to chloride, bromide, tetrafluoroborate, methyl sulfate, and hexafluorophosphate anions. For example, the imidazole structure can be as shown in FIG. 1, and the imidazole structure 110 can include hydrogen atoms, organic groups, or combinations thereof occupying positions 1, 2, and 3. In various embodiments, suitable organic groups can occupy the positions 1, 2, and 3, and may include, but are not limited to, saturated hydrocarbon, unsaturated hydrocarbon, and aromatic hydrocarbon groups. In alternate embodiments, the ionic fluid may comprise a pyridinium ion and a suitable anion, including but not limited to chloride, bromide, tetrafluoroborate, methyl sulfate, and hexafluorophosphate anions. For example, the pyridine cation structure can be as shown in FIG. 1, and the pyridine cation structure 160 can include hydrogen atoms, organic groups, or combinations thereof occupying positions 1, 2, 3, 4, and 5. In various embodiments, suitable organic groups can occupy positions 1, 2, 3, 4, and 5, and may include, but are not limited to, saturated hydrocarbon, unsaturated hydrocarbon, and aromatic hydrocarbon group.

Still referring to both FIGS. 2 and 3, during a second time T₂, the supercritical processing solution can be recirculated over the substrate and through the processing chamber 208 using the recirculation system 220, such as described above. In one embodiment, the process chemistry supply system 230 can be switched off, and process chemistry is not injected during the second time T₂. Alternatively, the process chemistry supply system 230 may be switched on one or more times during T₂, and process chemistry may be injected into the processing chamber 208 during the second time T₂ or after the second time T₂.

The processing chamber 208 can operate at a pressure above 1,500 psi during the second time T₂. For example, the pressure can range from approximately 2,500 psi to approximately 3,100 psi, but can be any value so long as the operating pressure is sufficient to maintain supercritical conditions. The supercritical processing solution is circulated over the substrate and through the processing chamber 208 using the recirculation system 220, such as described above. The supercritical conditions within the processing chamber 208 and the other elements in the recirculation loop 215 (FIG. 2) are maintained during the second time T₂, and the supercritical processing solution continues to be circulated over the substrate and through the processing chamber 208 and the other elements in the recirculation loop 215 (FIG. 2). The recirculation system 220 (FIG. 2), can be used to regulate the flow of the supercritical processing solution through the processing chamber 208 and the other elements in the recirculation loop 215 (FIG. 2).

Still referring to both FIGS. 2 and 3, during a third time T₃, one or more push-through processes can be performed. In one embodiment, the carbon dioxide supply system 240 can be operated during a push-through process and can be used to fill the recirculation loop with temperature-controlled fluid. The carbon dioxide supply system 240 can comprise means for providing a first volume of temperature-controlled fluid during a push-through process, and the first volume can be larger than the volume of the recirculation loop. Alternately, the first volume can be less than or approximately equal to the volume of the recirculation loop. In addition, the temperature differential within the first volume of temperature-controlled fluid during the push-through process can be controlled to be less than approximately 10 degrees Celsius. Alternately, the temperature variation of the temperature-controlled fluid can be controlled to be less than approximately 5 degrees Celsius during a push-through process.

In other embodiments, the carbon dioxide supply system 240 can comprise means for providing one or more volumes of temperature controlled fluid during a push-through process; each volume can be larger than the volume of the processing chamber or the volume of the recirculation loop; and the temperature variation associated with each volume can be controlled to be less than 10 degrees Celsius.

For example, during the third time T₃, one or more volumes of temperature controlled supercritical carbon dioxide can be fed into the processing chamber 208 and the other elements in the recirculation loop 215 from the carbon dioxide supply system 240, and the supercritical cleaning solution along with process residue suspended or dissolved therein can be displaced from the processing chamber 208 and the other elements in the recirculation loop 215 through the exhaust control system 260. In an alternate embodiment, supercritical carbon dioxide can be fed into the recirculation system 220 from the carbon dioxide supply system 240, and the supercritical cleaning solution along with process residue suspended or dissolved therein can also be displaced from the processing chamber 208 and the other elements in the recirculation loop 215 through the exhaust control system 260.

Providing temperature-controlled fluid during the push-through process prevents process residue suspended or dissolved within the fluid being displaced from the processing chamber 208 and the other elements in the recirculation loop 215 from dropping out and/or adhering to the processing chamber 208 and the other elements in the recirculation loop 215. In addition, during the third time T₃, the temperature of the fluid supplied by the carbon dioxide supply system 240 can vary over a wider temperature range than the range used during the second time T₂.

In the illustrated embodiment shown in FIG. 3, a single second time T₂ is followed by a single third time T₃, but this is not required. In alternate embodiments, other time sequences may be used to process a substrate.

After the push-through process is complete, a pressure cycling process can be performed. Alternately, one or more pressure cycles can occur during the push-through process. In other embodiments, a pressure cycling process is not required. During a fourth time T₄, the processing chamber 208 can be cycled through a plurality of decompression and compression cycles. The pressure can be cycled between a first pressure P₃ and a second pressure P₄ one or more times. In alternate embodiments, the first pressure P₃ and a second pressure P₄ can vary. In one embodiment, the pressure can be lowered by venting through the exhaust control system 260. For example, this can be accomplished by lowering the pressure to below approximately 1,500 psi and raising the pressure to above approximately 2,500 psi. The pressure can be increased by using the carbon dioxide supply system 240 and/or the pressure control system 250 to provide additional high-pressure fluid.

The carbon dioxide supply system 240 and/or the pressure control system 250 can comprise means for providing a first volume of temperature-controlled fluid during a compression cycle, and the first volume can be larger than the volume of the recirculation loop. Alternately, the first volume can be less than or approximately equal to the volume of the recirculation loop. In addition, the temperature differential within the first volume of temperature-controlled fluid during the compression cycle can be controlled to be less than approximately 10 degrees Celsius. Alternately, the temperature variation of the temperature-controlled fluid can be controlled to be less than approximately 5 degrees Celsius during a compression cycle.

In addition, the carbon dioxide supply system 240 and/or the pressure control system 250 can comprise means for providing a second volume of temperature-controlled fluid during a decompression cycle, and the second volume can be larger than the volume of the recirculation loop. Alternately, the second volume can be less than or approximately equal to the volume of the recirculation loop. In addition, the temperature differential within the second volume of temperature-controlled fluid during the decompression cycle can be controlled to be less than approximately 10 degrees Celsius. Alternately, the temperature variation of the temperature-controlled fluid can be controlled to be less than approximately 5 degrees Celsius during a decompression cycle.

In other embodiments, the carbon dioxide supply system 240 and/or the pressure control system 250 can comprise means for providing one or more volumes of temperature controlled fluid during a compression cycle and/o decompression cycle; each volume can be larger than the volume of the processing chamber or the volume of the recirculation loop; the temperature variation associated with each volume can be controlled to be less than 10 degrees Celsius; and the temperature variation can be allowed to increase as additional cycles are performed.

Furthermore, during the fourth time T₄, one or more volumes of temperature controlled supercritical carbon dioxide can be fed into the processing chamber 208 and the other elements in the recirculation loop 215, and the supercritical cleaning solution along with process residue suspended or dissolved therein can be displaced from the processing chamber 208 and the other elements in the recirculation loop 215 through the exhaust control system 260. In an alternate embodiment, supercritical carbon dioxide can be fed into the recirculation system 220, and the supercritical cleaning solution along with process residue suspended or dissolved therein can also be displaced from the processing chamber 208 and the other elements in the recirculation loop 215 through the exhaust control system 260.

Providing temperature-controlled fluid during the pressure cycling process prevents process residue suspended or dissolved within the fluid being displaced from the processing chamber 208 and the other elements in the recirculation loop 215 from dropping out and/or adhering to the processing chamber 208 and the other elements in the recirculation loop 215. In addition, during the fourth time T₄, the temperature of the fluid supplied can vary over a wider temperature range than the range used during the second time T₂.

In the illustrated embodiment shown in FIG. 3, a single third time T₃ is followed by a single fourth time T₄, but this is not required. In alternate embodiments, other time sequences may be used to process a substrate.

In an alternate embodiment, the exhaust control system 260 can be switched off during a portion of the fourth time T₄. For example, the exhaust control system 260 can be switched off during a compression cycle.

During a fifth time T₅, the processing chamber 208 can be returned to lower pressure. For example, after the pressure cycling process is completed, then the processing chamber can be vented or exhausted to atmospheric pressure.

The carbon dioxide supply system 240 and/or the pressure control system 250 can comprise means for providing a volume of temperature-controlled fluid during a venting process, and the volume can be larger than the volume of the recirculation loop. Alternately, the volume can be less than or approximately equal to the volume of the recirculation loop. In addition, the temperature differential within the volume of temperature-controlled fluid during the venting process can be controlled to be less than approximately 20 degrees Celsius. Alternately, the temperature variation of the temperature-controlled fluid can be controlled to be less than approximately 15 degrees Celsius during a venting process.

In other embodiments, the carbon dioxide supply system 240 and/or the pressure control system 250 can comprise means for providing one or more volumes of temperature controlled fluid during a venting process; each volume can be larger than the volume of the processing chamber or the volume of the recirculation loop; the temperature variation associated with each volume can be controlled to be less than 20 degrees Celsius; and the temperature variation can be allowed to increase as the pressure approaches the final pressure.

Furthermore, during the fifth time T₅, one or more volumes of temperature controlled supercritical carbon dioxide can be fed into the recirculation loop 215, and the remaining supercritical cleaning solution along with process residue suspended or dissolved therein can be displaced from the processing chamber 208 and the other elements in the recirculation loop 215 through the exhaust control system 260. In an alternate embodiment, supercritical carbon dioxide can be fed into the processing chamber 208 and/or the recirculation system 220, and the remaining supercritical cleaning solution along with process residue suspended or dissolved therein can also be displaced from the processing chamber 208 and the other elements in the recirculation loop 215 through the exhaust control system 260.

Providing temperature-controlled fluid during the venting process prevents process residue suspended or dissolved within the fluid being displaced from the processing chamber 208 and the other elements in the recirculation loop 215 from dropping out and/or adhering to the processing chamber 208 and the other elements in the recirculation loop 215.

In the illustrated embodiment shown in FIG. 3, a single fourth time T₄ is followed by a single fifth time T₅, but this is not required. In alternate embodiments, other time sequences may be used to process a substrate.

In one embodiment, during a portion of the fifth time T₅, the recirculation pump (not shown) can be switched off. In addition, the temperature of the fluid supplied by the fluid supply subassembly 200 can vary over a wider temperature range than the range used during the second time T₂. For example, the temperature can range below the temperature required for supercritical operation.

For substrate processing, the chamber pressure can be made substantially equal to the pressure inside of a transfer chamber (not shown) coupled to the processing chamber. In one embodiment, the substrate can be moved from the processing chamber into the transfer chamber, and moved to a second process apparatus or module to continue processing.

In the illustrated embodiment shown in FIG. 3, the pressure returns to an initial pressure P₀, but this is not required for the invention. In alternate embodiments, the pressure does not have to return to P₀, and the process sequence can continue with additional time steps such as those shown in time steps T₁, T₂, T₃, T₄, or T₅.

The graph 300 is provided for exemplary purposes only. For example, a low-k layer can be treated using 1 to 10 cleaning steps each taking less than approximately 3 minutes, as described above. It will be understood by those skilled in the art that a supercritical processing step can have any number of different time/pressures or temperature profiles without departing from the scope of the invention. Further, any number of cleaning, rinsing, and/or curing process sequences with each step having any number of compression and decompression cycles are contemplated. In addition, as stated previously, concentrations of various chemicals and species within a supercritical processing solution can be readily tailored for the application at hand and altered at any time within a supercritical processing step.

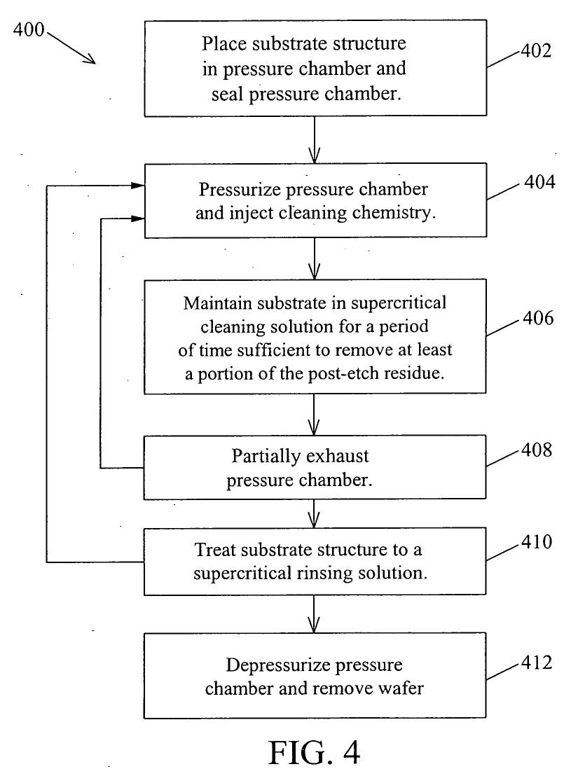

FIG. 4 shows a simplified flow diagram outlining steps for cleaning a substrate structure comprising a patterned low-k dielectric layer in accordance with the embodiments of the invention. In the illustrated embodiment, a method 400 is shown for cleaning a substrate structure comprising a patterned low-k dielectric layer with a supercritical process chemistry to remove a post-etch residue. Alternately, post-ash residue can also be cleaned.

In the step 402 a substrate structure with the post-etch residue, such as a post-etch photopolymer residue, spin-on anti-reflective polymer residue and/or polymer layers contaminated with inorganic elements, as described above, is placed within a pressure chamber and the pressure chamber is sealed.

After the substrate structure is placed within the pressure chamber in the step 402, then in the step 404 the pressure chamber is pressurized with CO₂ and the cleaning chemistry is added to the CO₂ to generate a supercritical cleaning solution.

After the supercritical cleaning solution is generated in the step 404, then in the step 406 the substrate structure is exposed to the supercritical cleaning solution and maintained in the supercritical cleaning solution for a period of time required to remove at least a portion of the residue material from the substrate structure. In addition, the supercritical cleaning solution is circulated through the processing chamber and/or otherwise flowed to move the supercritical cleaning solution over surfaces of the substrate structure.

Still referring to FIG. 4, after at least a portion of the residue is removed from the substrate in the step 406, the pressure chamber is partially exhausted in the step 408. The cleaning process comprising the steps 404 and 406 is repeated any number of times using substantially pure supercritical carbon dioxide, supercritical carbon dioxide and process chemistry, or both, as required to remove the residue from the substrate structure. Alternatively, the concentration of the cleaning chemistry may be modified by diluting the processing chamber with supercritical carbon dioxide, by adding different quantities of cleaning chemistry or a combination thereof.

Still referring to FIG. 4, after the cleaning process or cycle comprising the steps 404, 406 and 408 is complete, then the substrate structure, in accordance with the embodiments of the invention, is treated to a supercritical rinsing solution in the step 410. The supercritical rinsing solution preferably comprises supercritical CO₂ and one or more organic solvents, but can be substantially pure supercritical CO₂.

Still referring to FIG. 4, after the substrate structure is cleaned and rinsed in the step 410, then in the step 412 the pressure chamber is depressurized and the substrate structure is removed from the pressure chamber. Alternatively, the substrate structure is recycled through the cleaning process comprising the steps 404, 406, 408 and 410 as indicated by the arrow connecting the steps 410 and 404 and/or the substrate structure is cycled through several rinse cycles prior to removing the substrate structure from the pressure chamber in the step 412.

As described previously, the supercritical cleaning solution utilized in the present invention can also include one or more carrier solvents. Also, it will be clear to one skilled in the art that any number of different treatment sequences are within the scope of the invention. For example, cleaning steps and rinsing steps can be combined in any number of different ways to achieve removal of a residue from a substrate structure.

The present invention has the advantages of being sufficiently selective to remove post etch residues, including but not limited to spin-on polymeric anti-reflective coating layer and photopolymers, for patterned low-k dielectric layers without etching or attacking the patterned low-k silicon-based layer therebelow.

In addition, the substrate structure can be dried and/or pretreated before and/or after the supercritical cleaning process. Furthermore, the substrate structure can be dried and/or pretreated before and/or after the supercritical rinsing process. In addition, it will be clear to one skilled in the art that a semiconductor substrate comprising a patterned low-k dielectric layer and residue, such as post-etch residue and/or post-etch residue, can be treated to any number of cleaning, rinsing, drying, and pre-treating steps and/or sequences. For example, a supercritical rinse step is not always necessary and simply drying the substrate with a supercritical solution can appropriate for some applications.

The present invention has the advantages of being capable of passivating a low-k surface and being compatible with other processing steps, such as removing post-etch residues (including, but not limited to, spin-on polymeric anti-reflective coating layers and photopolymers) for patterned low-k layers in a supercritical processing environment. The present invention also has been observed to restore or partially restore k -values of materials lost after patterning steps and has been shown to produce low-k layers that are stable over time.

While the present invention has been described in terms of specific embodiments incorporating details to facilitate the understanding of the principles of construction and operation of the invention, such reference herein to specific embodiments and details thereof is not intended to limit the scope of the claims appended hereto. It will be apparent to those skilled in the art that modifications may be made in the embodiments chosen for illustration without departing from the spirit and scope of the invention. Specifically, while supercritical CO₂ is the preferred medium for cleaning, other supercritical media alone or in combination with supercritical CO₂ are contemplated.

1. A method of removing a residue from a substrate structure, the method comprising:
maintaining the substrate structure in a supercritical cleaning solution comprising supercritical CO₂ and an amount of an ionic fluid; and
removing the supercritical cleaning solution, thereby removing a first portion of the residue from the substrate structure.

2. The method of claim 1, wherein the ionic fluid comprises a heterocyclic salt.

3. The method of claim 2, wherein the heterocyclic salt is selected from the group consisting of imidazole salt and a pyridine salt.

4. The method of claim 3, wherein the heterocyclic salt comprises an imidazolium ion and at least one anion selected from the group consisting of a chloride anion, a bromide anion, a tetrafluoroborate anion, a methyl sulfate anion, and a hexafluorophosphate anion.

5. The method of claim 4, wherein the imidazolium ion is functionalized with at least one of a hydrogen atom, an organic group, or a combination thereof.

6. The method of claim 5, wherein the organic group comprises at least one of a saturated hydrocarbon group, an unsaturated hydrocarbon group, and aromatic hydrocarbon group, or a combination thereof.

7. The method of claim 3, wherein the heterocyclic salt comprises an pyridinium ion and at least one anion selected from the group consisting of a chloride anion, a bromide anion, a tetrafluoroborate anion, a methyl sulfate anion, and a hexafluorophosphate anion.

8. The method of claim 7, wherein the pyridinium ion is functionalized with at least one of a hydrogen atom, an organic group, or a combination thereof.

9. The method of claim 8, wherein the organic group comprises at least one of a saturated hydrocarbon group, an unsaturated hydrocarbon group, and aromatic hydrocarbon group, or a combination thereof.

10. The method of claim 1, wherein the cleaning solution further comprises a carrier solvent.

11. The method of claim 10, wherein the carrier solvent is selected from the group consisting of N,N-dimethylacetamide (DMAc), gamma-butyrolactone (BLO), dimethyl sulfoxide (DMSO), ethylene carbonate (EC), N-methylpyrrolidone (NMP), dimethylpiperidone, propylene carbonate, alcohol, and combinations thereof.

12. The method of claim 1, wherein the residue comprises a post-etch residue, or a post-ash residue, or a combination thereof.

13. The method of claim 1, wherein the substrate structure is maintained at temperatures in a range of approximately 40 degrees Celsius to approximately 250 degrees Celsius.

14. The method of claim 1, wherein the supercritical cleaning solution is maintained at temperatures in a range of approximately 40 degrees Celsius to approximately 250 degrees Celsius.

15. The method of claim 1, wherein the substrate structure comprises a low-k dielectric layer, or an ultra low-k layer or a combination thereof.

16. The method of claim 1, wherein the substrate structure comprises a material selected from the group consisting of carbon-doped oxide (COD), spin-on-glass (SOG), and fluoridated silicon glass (FSG).

17. The method of claim 1, further comprising washing the substrate structure with a supercritical rinsing solution after removing the supercritical cleaning solution and the residue away from the substrate material.

18. The method of claim 17, wherein the supercritical rinsing solution comprises CO₂ and an organic solvent.

19. The method of claim 18, wherein the organic solvent is selected from the group consisting of N, N-dimethylacetamide (DMAc), gamma-butyrolactone (BLO), dimethyl sulfoxide (DMSO), ethylene carbonate (EC), N-methylpyrrolidone (NMP), dimethylpiperidone, propylene carbonate, alcohol, and combinations thereof.

20. The method of claim 1, wherein the first portion of the residue comprises substantially all of the residue.

21. The method of claim 1, further comprising:
providing an additional amount of the supercritical cleaning solution to the substrate structure; and
removing the additional amount of the supercritical cleaning solution, thereby removing a second portion of the residue from the substrate structure.

22. A method of forming a patterned dielectric layer, the method comprising;
depositing a continuous layer of dielectric material;
forming a photoresist mask over the continuous layer of dielectric material;
patterning the continuous layer of dielectric material through the photoresist mask thereby forming a post-etch residue; and
removing the post-etch residue using a supercritical cleaning solution comprising supercritical carbon dioxide and an amount of an ionic fluid.

23. The method of claim 22, wherein the ionic fluid comprises a heterocyclic salt.

24. The method of claim 23, wherein the heterocyclic salt is selected from the group consisting of imidazole salt and a pyridine salt.

25. The method of claim 24, wherein the heterocyclic salt comprises an imidazolium ion and at least one anion selected from the group consisting of a chloride anion, a bromide anion, a tetrafluoroborate anion, a methyl sulfate anion, and a hexafluorophosphate anion.

26. The method of claim 25, wherein the imidazolium ion is functionalized with at least one of a hydrogen atom, an organic group, or a combination thereof.

27. The method of claim 26, wherein the organic group comprises at least one of a saturated hydrocarbon group, an unsaturated hydrocarbon group, and aromatic hydrocarbon group, or a combination thereof.

28. The method of claim 24, wherein the heterocyclic salt comprises an pyridinium ion and at least one anion selected from the group consisting of a chloride anion, a bromide anion, a tetrafluoroborate anion, a methyl sulfate anion, and a hexafluorophosphate anion.

29. The method of claim 28, wherein the pyridinium ion is functionalized with at least one of a hydrogen atom, an organic group, or a combination thereof.

30. The method of claim 24, wherein the organic group comprises at least one of a saturated hydrocarbon group, an unsaturated hydrocarbon group, and aromatic hydrocarbon group, or a combination thereof.

31. The method of claim 22, wherein the cleaning solution further comprises a carrier solvent.

32. The method of claim 31, wherein the carrier solvent is selected from the group consisting of N, N-dimethylacetamide (DMAc), gamma-butyrolactone (BLO), dimethyl sulfoxide (DMSO), ethylene carbonate (EC), N-methylpyrrolidone (NMP), dimethylpiperidone, propylene carbonate, alcohol, and combinations thereof.

33. The method of claim 22, wherein the dielectric material comprises a low-k dielectric layer, or an ultra low-k layer or a combination thereof.

34. The method of claim 22, wherein the dielectric material is maintained at temperatures in a range of approximately 40 degrees Celsius to approximately 250 degrees Celsius.

35. The method of claim 22, wherein the supercritical cleaning solution is maintained at temperatures in a range of approximately 40 degrees Celsius to approximately 250 degrees Celsius.

36. The method of claim 1, wherein the supercritical cleaning solution is maintained at pressures in a range of approximately 1,000 psi to approximately 9,000 psi.

37. A method of forming a patterned dielectric layer, the method comprising;
depositing a continuous layer of dielectric material;
forming a photoresist mask over the continuous layer of dielectric material;
patterning the continuous layer of dielectric material through the photoresist mask;
removing the photoresist mask, thereby forming a post-ash residue; and
removing the post-ash residue using a supercritical solution comprising supercritical carbon dioxide and a ionic fluid.
